(19) United States
(12) Patent Application Publication
(10) Pub. No.: US 2025/0370861 A1
(43) Pub. Date: Dec. 4, 2025

(54) NOR FLASH MEMORY AND OPERATION METHOD THEREOF

(71) Applicant: Winbond Electronics Corp., Taichung City (TW)

(72) Inventor: Masaru Yano, Tokyo (JP)

(73) Assignee: Winbond Electronics Corp., Taichung City (TW)

(21) Appl. No.: 19/058,009

(22) Filed: Feb. 20, 2025

(30) Foreign Application Priority Data
Jun. 3, 2024 (JP) 2024-089804

(51) Int. Cl. G06F 11/10

(52) U.S. Cl. CPC G06F 11/1044

(57) ABSTRACT

A NOR flash memory suitable for protecting data requiring high reliability and an operation method thereof are provided. The NOR flash memory includes a memory cell array, including a plurality of memory cells; an ECC component for performing error checking and correcting on data read from the memory cell array; an error identification component for identifying an error pattern of a faulty memory cell for which error checking and correcting have been performed by the ECC component; and a recovery component for performing recovery on the faulty memory cell based on the identified error pattern to eliminate errors in the faulty memory cell.

### CROSS-REFERENCE TO RELATED APPLICATION

This application claims the priority benefit of Japan application serial no. 2024-089804, filed on Jun. 3, 2024. The entirety of the above-mentioned patent application is hereby incorporated by reference herein and made a part of this specification.

### BACKGROUND

### Technical Field

The disclosure relates to a NOR flash memory and an operation method thereof, and particularly relates to a NOR flash memory equipped with an ECC function.

### Description of Related Art

In NAND (Not-AND) flash memory, due to repeated reading/programming/erasing, threshold voltage fluctuations may occur due to the deterioration of the tunnel insulating film or the deterioration of Gm (transconductance), which may sometimes cause bit errors. As a countermeasure against such bit errors, an error detection and correction function (hereinafter referred to as an error checking and correcting (ECC) function) is used (for example, Japanese Patent No. 7253594).

Since the memory cells of the NOR (Not-OR) flash memory are connected in parallel, the memory cells may be accessed in units of bits, so the impact of interference (disturbance), etc. is small, which is different from the NAND flash memory. In comparison, the probability of bit errors occurring is also small. Therefore, the NOR flash memory is suitable for storing data with high reliability requirements, such as boot data or code used to start system operations.

In recent years, the data capacity of boot data or code has increased. On the other hand, the memory capacity of the NOR flash memory has also been increasing due to the miniaturization of the memory size. With the memory cells shrinking, even NOR flash memory may not ignore the generation of bit errors, and the incorporation of ECC function continues to be under consideration.

However, merely correcting errors through the ECC function is not sufficient to protect data that requires high reliability. For example, when booting a system or starting software, boot data is read from NOR flash memory, but the boot data is read more frequently than other data. Therefore, the probability of errors occurring in the boot data is higher than in other data. If the number of errors exceeds the number of bits that may be corrected by the ECC function, the errors in the boot data may not be corrected, which is fatal for the system started by the boot data.

### SUMMARY

The purpose of the disclosure is to solve this existing problem and provide a NOR flash memory suitable for protecting data requiring high reliability and an operation method thereof.

A NOR flash memory of the disclosure includes a memory cell array, including a plurality of memory cells; an ECC component for performing error checking and correcting on data read from the memory cell array; an error identification component for identifying an error pattern of a faulty memory cell for which error checking and correcting have been performed by the ECC component; and a recovery component for performing recovery on the faulty memory cell based on the identified error pattern to eliminate errors in the faulty memory cell.

In one embodiment, when the error pattern indicates a decrease in a threshold of the memory cell, the recovery component programs the faulty memory cell to increase the threshold. In one embodiment, the error identification component maintains an address of the faulty memory cell, and the recovery component programs the faulty memory cell based on the address. In one embodiment, when the error pattern indicates an increase in the threshold of the memory cell, the recovery component increases the read verification voltage of the faulty memory cell. In one embodiment, the error identification component stores the address of the faulty memory cell, and the recovery component increases the read verification voltage when reading the faulty memory cell based on the address. In one embodiment, the NOR flash memory further includes a management component for managing the generation of faulty memory cells in a sector of the memory cell array; and a transmitting component for transmitting the data of the sector containing the faulty memory cell to a redundant area of the memory cell array based on a management result of the management component. In one embodiment, the memory cell array includes a boot data storage area for storing boot data, and the recovery component performs recovery on the faulty memory cells that store the boot data.

An operation method performed by a NOR flash memory of the disclosure includes a step of performing error checking and correcting on data read from a memory cell array through a ECC component; a step of identifying an error pattern of a faulty memory cell for which error checking and correcting have been performed by the ECC component; and a step of performing recovery on the faulty memory cell based on the identified error pattern to eliminate errors in the faulty memory cell.

In one embodiment, when the error pattern indicates a decrease in a threshold of a memory cell, the recovery step includes programming the faulty memory cell to increase the threshold. In one embodiment, when the error pattern indicates an increase in the threshold of the memory cell, the recovery step includes increasing the read verification voltage of the faulty memory cell.

According to the disclosure, recovery is performed on the faulty memory cell to eliminate errors in the faulty memory cell for which error checking and correcting have been performed. Therefore, the error checking and correcting function of the ECC component may be given a margin. As a result, high reliability of data may be maintained.

### BRIEF DESCRIPTION OF THE DRAWINGS

FIG. 1 is a block diagram showing a schematic structure of a NOR flash memory according to an embodiment of the disclosure.

FIG. 2 is a diagram showing a structural example of a boot storage area and a boot management area according to the embodiment of the disclosure.

FIG. 3A shows an error migrating in the direction of decreasing threshold of the memory cell.

FIG. 3B is a diagram illustrating recovery for the error.

FIG. 4A shows an error migrating in the direction of increasing threshold of the memory cell.

FIG. 4B is a diagram illustrating recovery for the error.

FIG. 5 is an operation flow for programming boot data in the embodiment.

FIG. 6 is an operation flow for reading boot data of the embodiment.

FIG. 7 is a diagram showing an example of a boot management area updated when reading boot data.

FIG. 8 is an operation flow for replacing boot data according to another embodiment of the disclosure.

### DESCRIPTION OF THE EMBODIMENTS

The NOR flash memory of the disclosure includes a memory management scheme, which is suitable for protecting data that requires high reliability, such as boot data or code read when booting a system or starting software. This scheme strives to eliminate errors in the stored data, thereby providing highly reliable data.

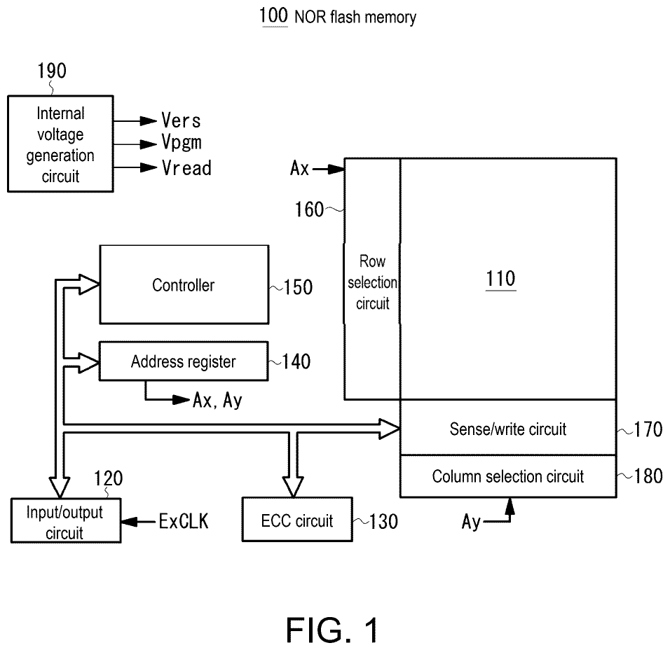

As shown in FIG. 1, a NOR flash memory 100 of the embodiment includes the following components: a memory cell array 110 including a plurality of memory cells; an input/output circuit 120 for synchronously outputting read data to the outside with a clock signal ExCLK, or receiving data input from the outside; an ECC circuit 130 for generating codes for data to be programmed, or performing error checking and correcting on read data; an address register 140 for receiving address data via the input/output circuit 120; a controller 150 for controlling operations based on command data received via the input/output circuit 120 or control signals applied to the external terminals; a row selection circuit 160 for receiving a row address information Ax from the address register 140, decoding the row address information Ax, and selecting word lines or sectors based on the decoding result; a sense/write circuit 170 for reading the data read from the memory cell selected by the row selection circuit 160, or writing the programmed data to the selected memory cell; a column selection circuit 180 for receiving a column address information Ay from the address register 140, decoding the column address information Ay, and selecting bit lines/source lines based on the decoding result; and an internal voltage generation circuit 190 for generating various voltages (programming voltage Vpgm, read voltage Vread, erase voltage Vers, etc.) required for reading, programming, and erasing data.

The memory cell array 110 includes a plurality of memory cells arranged in rows and columns, and each memory cells is connected in parallel between a bit line and a source line. That is, it has a NOR structure. The memory cell may be a two-dimensional structure formed on the surface of a substrate, such as silicon, or a three-dimensional structure formed vertically from the surface of the substrate. In addition, the memory cell may be a single level cell (SLC) storing binary data, or a multi level cell (MLC) storing multi-level data.

The input/output circuit 120 synchronously receives commands, addresses, data, etc. from the host system with the clock signal ExCLK, and provides the received commands, addresses, and data to the controller 150, the address register 140, the column selection circuit 180, and the sense/write circuit 170. In addition, the input/output circuit 120 receives the data read from the memory cell array 110 via the sense/write circuit 170 and provides the same to the host system.

The ECC circuit 130 includes an encoder that encodes data to generate ECC codes, and a decoder that decodes the data based on the ECC codes. During programming operations, the ECC circuit 130 generates the ECC codes necessary for error checking and correcting of input data by performing calculations on bit strings of data input via the input/output circuit 120. During read operations, error checking and correcting of data read from the memory cell array 110 are performed based on the ECC codes.

The number of bits that may be used for error checking and correcting using the ECC circuit 130 is not particularly limited. The ECC circuit 130 may perform error checking and correcting using, for example, Hamming Code, Reed-Solomon Codes, or Bose-Chaudhuri-Hocquenghem Code (BCH Code). In the case of BCH Code, it may perform multi-bit (e.g., 2-bit, 4-bit, 8-bit, etc.) error checking and correcting. Additionally, the ECC circuit 130 may correct (bit inversion) error bits in the read data held by the sense/write circuit 170, or the ECC circuit 130 may receive the read data, perform error correcting on it, and output the error-corrected data to the sense/write circuit 170.

The controller 150 is composed of hardware and/or software resources, such as a microcontroller or state machine including read-only memory (ROM)/random access memory (RAM). The controller 150 receives commands from the host system and controls overall operations such as reading, programming, and erasing based on the commands.

When reading a memory cell, a certain positive voltage is applied to the selected word line through the row selection circuit 160, and the current or voltage flowing between the selected bit line/selected source line is read out by the sense/write circuit 170. When programming (writing) to the memory cell, a programmed voltage is applied to the selected word line through the row selection circuit 160, and a voltage corresponding to the data to be programmed is applied to the selected bit line through the sense/write circuit 170, causing the hot electrons flowing from the selected bit line to the selected source line to accumulate in the charge storage layer. However, the writing method may be a method other than this, and it may also capture charge in the charge storage layer through Fowler-Nordheim (FN) tunneling. The memory cell is erased by applying a certain voltage to the selected word line, such as injecting a hot hole into the charge storage layer, or applying an erase voltage to the substrate, so that the charge accumulated in the charge storage layer are discharged through FN tunneling. Memory cell erasing may be performed in units of sectors including a plurality of memory cells, but it can also be performed in units of memory cells.

When faulty memory cells (error bits) are detected by the ECC circuit 130, the memory management scheme of the embodiment identifies the error pattern, and performs recovery on faulty memory cells to eliminate errors in the faulty memory cells based on the identified error pattern. Through the recovery of faulty memory cells, it may ensure that error correcting may be performed within the range where error checking and correcting may be performed using the ECC circuit 130, thereby increasing the reliability of data.

In addition, in another pattern, the recovery of faulty memory cells is performed during the replacement period of data in faulty memory cells. In other words, in parallel with the recovery of faulty memory cells, data stored in faulty memory cells or sectors including faulty memory cells is transmitted to a new redundant area, and the recovery of faulty memory cells is completed. The generation of faulty memory cells is a precursor to failure. By avoiding the storage area where faulty memory cells have been generated, the generation of faulty memory cells may be further suppressed.

The memory management scheme of the embodiment is implemented for data that requires high reliability. Here, boot data is used as an example of such data. Boot data (boot code) is data necessary for system operation, and it is data that is protected by being distinguished from normal data used by users. Boot data is read from the memory cell array and provided to the external host system when the system operates or when power is supplied to the flash memory. If a part of the boot data disappears or is partially rewritten, it may cause obstacles to system operation. Therefore, high reliability is required for boot data.

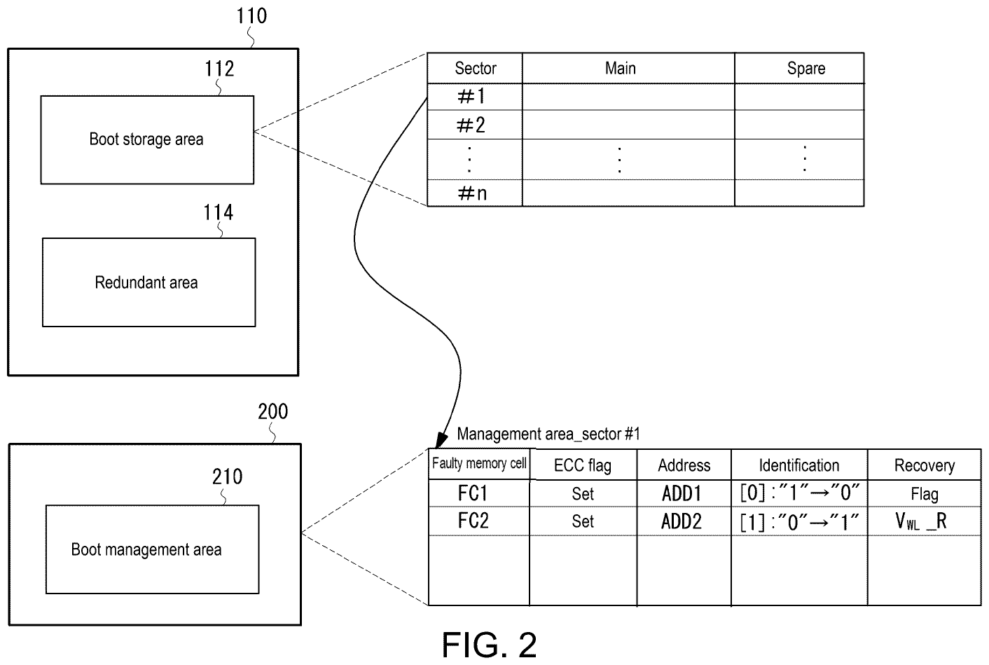

FIG. 2 shows a schematic example of data stored in the memory cell array and RAM. The memory cell array 110 not only includes an area used by users to store general data, but also includes a boot storage area 112 for storing boot data and a redundant area 114. On the other hand, a RAM 200 is a type of volatile memory, such as static random access memory (SRAM), which is typically set in the controller 150. The RAM 200 includes a boot management area 210 for storing management information of boot data. The boot storage area 112 and the redundant area 114 may be set at any address space in the memory cell array 110, and information related to the set address space is stored, for example, in the fuse ROM of the memory cell array 110. Various information related to the operation of the NOR flash memory 100 is stored in the fuse ROM. When starting up the NOR flash memory 100, the data stored in the fuse ROM is loaded into configuration registers, etc. to be referenced by the controller 150.

The boot data is input via the input/output circuit 120, and the controller 150 writes the input boot data into the main area of the boot storage area 112. In addition, the ECC circuit 130 performs computational processing on the input boot data to generate ECC codes required for error checking and correcting, and the generated ECC codes are written into the spare area of the boot storage area 112.

As shown in FIG. 2, the boot storage area 112 has a plurality of sectors #1 to #n (or a plurality of blocks). A memory cell connected to a word line may be referred to as a page, and a sector is composed of a plurality of pages. The sector includes a main area that may be accessed by users, and a spare area that may not be accessed by users. The boot data is stored in the main area, while the attribute information of the data written to the main area, such as ECC codes of the boot data generated by the ECC circuit 130, is stored in the spare area. Furthermore, the ECC codes of the boot data may be managed on a sector-by-sector basis or on a page-by-page basis.

On the other hand, the boot management area 210 of the RAM 200 stores information such as identification information for identifying ECC flags indicating faulty memory cells (error bits) detected by the ECC circuit 130 during the read operation of boot data or faulty memory cells that have been corrected, addresses of faulty memory cells, error patterns of faulty memory cells, and information related to the recovery of faulty memory cells corresponding to the error patterns. Furthermore, although not illustrated here, the boot management area 210 may include a look-up table (LUT) that specifies the address correspondence relationship between the boot storage area 112 and the redundant area 114.

The boot management area 210 is not particularly limited. For example, the boot data in the boot storage area 112 is managed on a sector-by-sector basis. FIG. 2 illustrates a management area_sector #1 for storing the management information of the sector #1 of the boot storage area 112. The management area_sector #1 includes faulty memory cells, ECC flags, addresses of faulty memory cells, identification of error patterns of faulty memory cells, and recovery information corresponding to the error patterns.

For example, when a faulty memory cell FC1 is detected during the reading of boot data in the sector #1, the faulty memory cell FC1 is registered in the management area_sector #1, an ECC flag indicating that the faulty memory cell FC1 is an error bit or has been error-corrected is set, and the address of the faulty memory cell FC1 is saved. Furthermore, the identification of the error pattern of the faulty memory cell FC1 is saved. In this example, data “O” indicating that the faulty memory cell FC1 has migrated from data “1” to data “O” is illustrated as identification information. In other words, this means that the faulty memory cell FC1 has been corrected from data “0” to data “1” through the ECC circuit 130.

In addition, when another faulty memory cell FC2 is detected during the reading of the sector #1, the faulty memory cell FC2 is registered, the ECC flag for the faulty memory cell FC2 is set, and the address of the faulty memory cell FC2 is saved. As for the identification of the error pattern of the faulty memory cell FC2, in this case, data “1” indicating that the faulty memory cell FC2 has migrated from data “O” to data “1” is illustrated as identification information. In other words, this means that the faulty memory cell FC2 has been corrected from data “1” to data “0” through the ECC circuit 130.

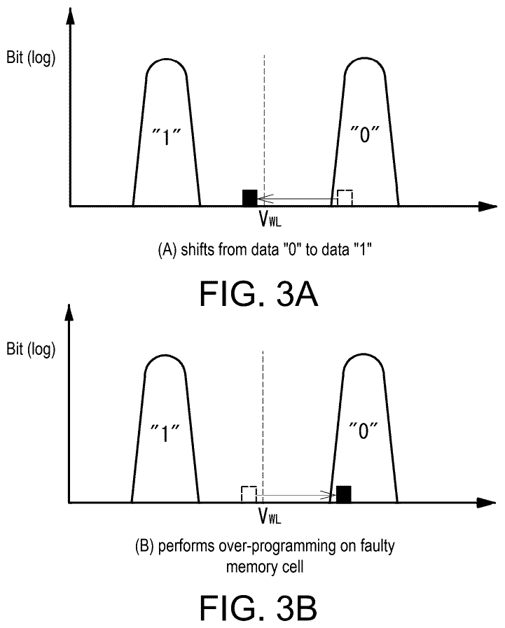

Next, the relationship between error patterns and recovery is explained. FIG. 3A illustrates an error when the data of a memory cell migrates from “0” to “1” (i.e., the threshold of the faulty memory cell decreases □ from to ▪). The threshold of a memory cell after programming data “0” must be greater than the read verification voltage VWL, but in a faulty memory cell where the threshold migrates towards a value less than the read verification voltage VWL, data “1” may be read even though data “0” was programmed. This error is generated due to charge loss in the memory cell, gradual decrease of the threshold, and deterioration of retention characteristics.

In the embodiment, as a recovery for this type of error based on retention characteristics, the address of the faulty memory cell is saved in the boot management area 210. Subsequently, over-programming is performed on the faulty memory cell to ensure that the threshold of the faulty memory cell exceeds the read verification voltage VWL at any given time, and the faulty memory cell is refreshed. This condition is shown in FIG. 3B (the threshold of the faulty memory cell increases from □ to ▪). For example, when the programming voltage used in the previous programming is known, a programming voltage higher than the previous programming voltage may be applied to the faulty memory cell, so as to increase the threshold of the memory cell in the positive direction; if it is not known, over-programming may be performed using the incremental step pulse program (ISPP) method, similar to the case with normal memory cells. Finally, the over-programming is terminated at the time when the programming verification is successful. A flag indicating whether the over-programming has been completed is set in the recovery related to the faulty memory cell FC1 in the boot management area.

Unlike NAND flash memory, in NOR flash memory, memory cells are connected in parallel, making it easier to program only the faulty memory cell and suppress programming disturbance to non-selected memory cells as in NAND memory cells. By performing recovery on the faulty memory cell through over-programming, bit errors of the recovered faulty memory cell may not be detected during the next boot data reading. As a result, this may provide margin for the number of bits that may be used for error checking and correcting by the ECC circuit 130, ensuring that the number of error bits in the boot data does not exceed the number of bits that may be used for error checking and correcting by the ECC circuit 130, thereby improving the reliability of the boot data.

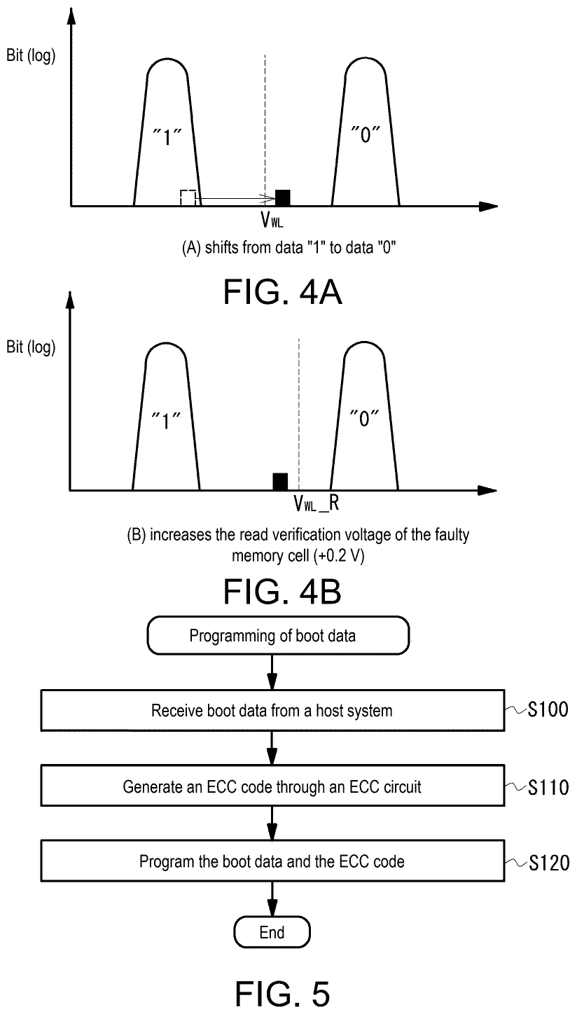

FIG. 4A plots the error when the memory cell data migrates from “1” to “0” (the threshold of the faulty memory cell increases from □ to ▪). The threshold of a memory cell with data “1”, i.e., an erased cell, must be lower than the read verification voltage VWL. However, in a faulty memory cell where the threshold migrates towards a value greater than the read verification voltage VWL, even though it has been erased to data “1”, it may still read as data “0”. This error occurs because boot data is read more frequently than other data, and when a memory cell with data “1” is read a plurality of times, the Gm (transconductance) deteriorates due to the current flowing through the memory cell, gradually increasing the threshold.

As a recovery for the error due to threshold increase, a new read verification voltage VWL_R is set to increase the verification voltage VWL by ΔV when reading the faulty memory cell. ΔV may be set to a predetermined value (e.g., 0.2 V), which may be determined by empirical rules. FIG. 4B illustrates the recovery process. The threshold of the recovered faulty memory cell is lower than the new read verification voltage VWL_R, and during the read operation, the read data from the recovered faulty memory cell becomes “1”. The newly set read verification voltage VWL_R is saved in the recovery of the faulty memory cell FC2 in the boot management area 210. Thus, in the next read operation, the recovered faulty memory cell may not be detected as an error bit, providing margin for the number of bits that may be used for error correcting by the ECC circuit 130, thereby improving the reliability of the boot data.

In addition, in the condition where the recovered faulty memory cell is again detected as an error bit by the ECC circuit 130, the read verification voltage VWL_R set in the boot management area 210 may also be further increased by ΔV.

Next, the operation of the NOR flash memory in the embodiment is explained. FIG. 5 shows the operation flow for programming boot data into the boot storage area. In the NOR flash memory 100, when a command, address, and boot data for programming the boot data are received from the host system via the input/output circuit 120 (S100), the ECC circuit 130 performs computational processing on the received boot data to generate an ECC code (S110).

The controller 150 controls the programming of the boot data based on the received command, and programs the boot data and ECC code into the selected sector in the boot storage area 112 through the row selection circuit 160 and column selection circuit 180, based on the address held in the address register 140 (S120). The boot data is written to the main area, and ECC code is written to the spare area. Moreover, in the condition where the location for storing the boot data is predetermined, it may not be necessary to receive the address from the host system. For example, the address for storing the boot data may be saved in a fuse ROM, and the controller 150 may refer to the address saved in the fuse ROM to program the boot data into the boot storage area 112.

Next, the read operation for boot data is explained. When reading the boot data, the controller 150 refers to the information saved in the boot management area 210 to control the reading of the boot data, and updates the management information for the boot data.

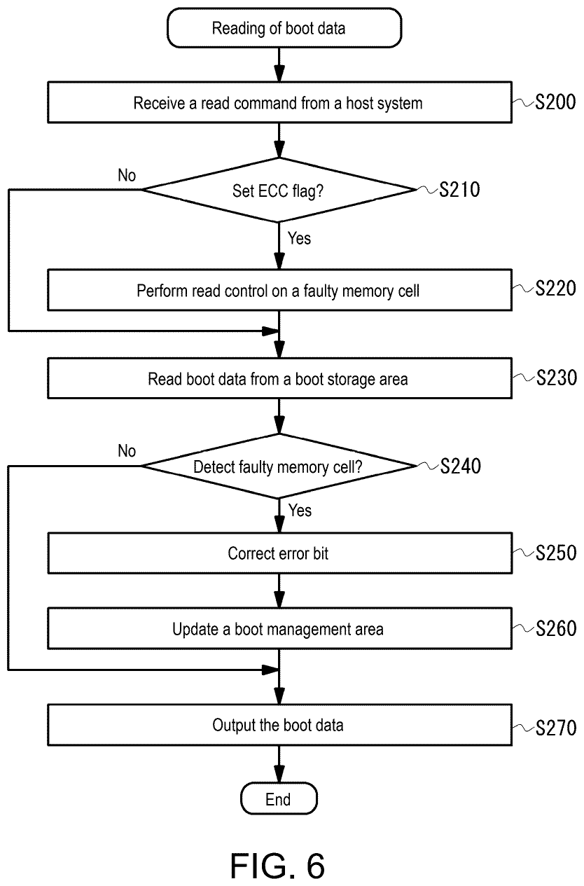

FIG. 6 shows the operation flow for reading boot data. When a command for reading the boot data is received from the host system (S200), the controller 150 reads the management information corresponding to the selected sector of the boot storage area 112 from the boot management area 210, and detects faulty memory cells with ECC flags set in the sector (S210). For example, when reading the boot data of the sector #1 shown in FIG. 2, the controller 150 detects the faulty memory cell FC1 and the faulty memory cell FC2 with ECC flags set.

When a faulty memory cell with the ECC flag set is detected, the controller 150 performs read control corresponding to the error pattern (S220). Specifically, for the faulty memory cell corresponding to the identification of the error pattern “1”, based on the address of the faulty memory cell stored in the boot management area 210, a read control is performed such that the read verification voltage used when reading the fault memory cell is changed to the read verification voltage VWL_R set during recovery. On the other hand, for the faulty memory cell corresponding to the identification of the error pattern “0”, at an appropriate time point after the error checking, the over-programming of the faulty memory cell has been completed, and the recovery flag is set.

Next, the controller 150 applies the read verification voltage VWL to the word line when reading the selected memory cells, and applies the read verification voltage VWL_R to the word line when reading the faulty memory cells, so as to read the boot data from the boot storage area (S230). During the reading of the boot data, the ECC circuit 130 detects whether faulty memory cells (error bits) have been generated in the boot data based on the ECC code (S240). As mentioned above, recovered faulty memory cells are not detected as error bits, but in the condition where new errors are generated in memory cells other than the recovered faulty memory cells, the faulty memory cells are detected.

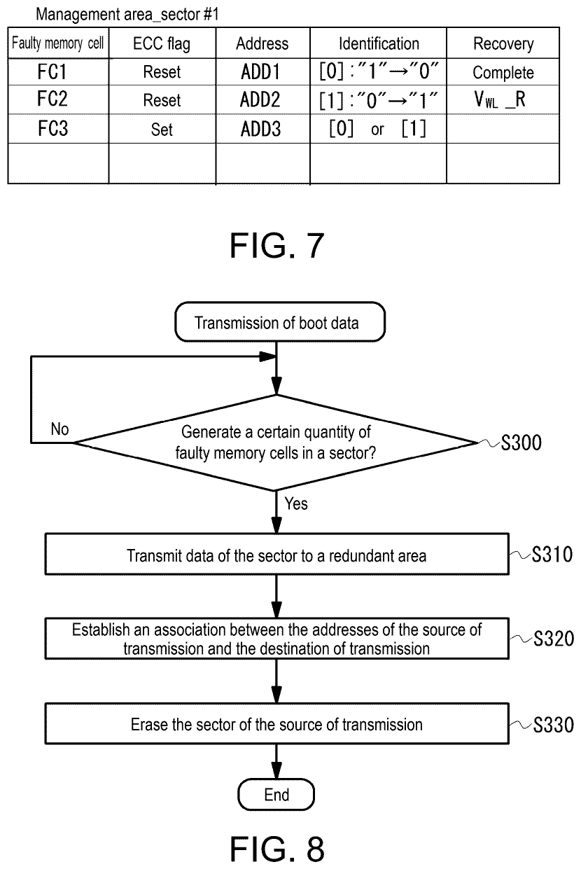

In the condition where an error is detected, the ECC circuit 130 performs correction of the error in the new faulty memory cell (S250), and the controller 150 updates the data related to the newly detected faulty memory cell to the boot management area (S260). For example, in the condition where a new faulty memory cell FC3 is detected during the reading of the sector #1, as shown in FIG. 7, the faulty memory cell FC3 is registered in the management area_sector #1, the ECC flag is set and the address is saved, and the identification of the error pattern is saved. Additionally, the ECC flags for the faulty memory cell FC1 and the faulty memory cell FC2 are rewritten to be reset. Then, the read boot data is output to the host system via the input/output circuit 120 (S270).

Thus, according to the embodiment, the error pattern of the faulty memory cells for which error checking and correcting have been performed by the ECC circuit 130 is identified, and the faulty memory cells are recovered based on the error pattern, thereby ensuring the error checking and correcting function of the ECC circuit 130, which may maintain the reliability of the boot data.

In the aforementioned embodiment, the boot management area 210 is set in the RAM 200 of the controller 150, but when the NOR flash memory 100 is powered off, the data stored in the RAM 200 is lost. Therefore, it may be ideal to backup the data of the boot management area 210 to a non-volatile memory, such as the memory cell array 110, during the power-off sequence of the NOR flash memory 100. When restarting the NOR flash memory 100, the loss of data in the boot management area may be prevented by loading the backed-up data into the boot management area 210.

Next, another embodiment will be explained. In the above-mentioned embodiment, the error correcting function of the ECC circuit 130 is maximized by performing recovery on faulty memory cells, ensuring the reliability of the boot data, but in the embodiment, the reliability of the boot data is further improved by limiting the recovery period.

The generation of the faulty memory cells signifies a precursor to sector failure caused by a plurality of reads, and additionally, performing recovery as shown in FIG. 4B (increasing the read verification voltage) may easily produce errors as shown in FIG. 3A (the threshold of the memory migrates towards a value less than the read verification voltage). Therefore, continuing the recovery of faulty memory cells may result in increasing the probability of generating the faulty memory cells, which reduces the reliability of the boot data.

Therefore, in the embodiment, a sector with a certain quantity of generated faulty memory cells (referred to as a faulty sector for convenience) is determined to be unsuitable for protecting high reliability data, and the data stored in the faulty sector is replaced to a new sector in the redundant area 114. After replacement, the data in the faulty sector is erased, and the faulty sector is reused as an area for storing general data. The replacement of such faulty sectors is related to wear leveling, which implements equalization of usage frequency of the memory cell array.

FIG. 8 indicates the operation flow for replacing boot data. The controller 150 refers to the boot management area 210 to determine whether a certain quantity of faulty memory cells has been generated in a sector (S300). The boot management area 210 manages the faulty memory cells on a sector-by-sector basis, where the history of the faulty memory cells generated in the sector is stored. The certain quantity may be arbitrarily decided, for example, it may be one faulty memory cell, or it may be a plurality of faulty memory cells.

When determining that a certain quantity of faulty memory cells has been generated in a sector, the controller 150 transmits the data of the sector to a new sector in the redundant area 114 (S310). When replacing data between sectors, the controller 150 registers the relationship between the address of the source sector and the address of the destination sector in a lookup table or the like in the boot management area 210, and establishes an association between the two (S320). After the transmission is complete, the controller 150 erases the data of the faulty sector that was the source of transmission (S330).

Thus, when a certain quantity of faulty memory cells is generated in a sector, by replacing the boot data to a new sector, the boot data may be protected to minimize errors in the boot data and improve its reliability. Additionally, through the replacement of boot data, equalization of usage frequency of sectors in the memory cell array may be implemented.

Next, a variation example will be explained. In the above embodiment, the boot data is replaced when a certain quantity of faulty memory cells is generated in a sector, but in the variation example, the controller 150 refers to the ECC flag in the boot management area, and when at least one ECC flag is detected to be set in a sector, it transmits the boot data of the sector to a sector in the redundant area. After the data transmission is complete, the controller 150 erases the data of the source sector.

In the explanation of the embodiment, the boot data (boot code) is exemplified as data requiring high reliability, but such data is not limited to the boot data. It may also be other specific data that should be protected, equivalent to boot data, which may be arbitrarily defined by the user. Additionally, in the embodiment, an example of storing the ECC flag in the boot management area is shown, but this is just one example. The ECC flag may also be stored in the spare area in the sector.

The embodiments of the present disclosure have been described in detail, but the present disclosure is not limited to specific embodiments, as various modifications and changes may be made within the scope of the subject of the present disclosure described in the claims.

What is claimed is:

1. A NOR flash memory, comprising:
a memory cell array, comprising a plurality of memory cells;
an error checking and correcting component, performing error checking and correcting on data read from the memory cell array;
an error identification component, identifying an error pattern of a faulty memory cell for which error checking and correcting have been performed by the error checking and correcting component; and
a recovery component, performing recovery on the faulty memory cell based on the identified error pattern to eliminate errors in the faulty memory cell.

2. The NOR flash memory according to claim 1, wherein when the error pattern indicates a decrease in a threshold of the memory cell, the recovery component programs the faulty memory cell to increase the threshold.

3. The NOR flash memory according to claim 2, wherein the error identification component stores an address of the faulty memory cell, and
the recovery component programs the faulty memory cell based on the address.

4. The NOR flash memory according to claim 1, wherein when the error pattern indicates an increase in a threshold of the memory cell, the recovery component increases a read verification voltage of the faulty memory cell.

5. The NOR flash memory according to claim 4, wherein the error identification component stores an address of the faulty memory cell, and
the recovery component increases the read verification voltage when reading the faulty memory cell based on the address.

6. The NOR flash memory according to claim 1, further comprising:
a management component, managing a generation of the faulty memory cell in a sector of the memory cell array; and
a transmitting component, transmitting the data of the sector containing the faulty memory cell to a redundant area of the memory cell array based on a management result of the management component.

7. The NOR flash memory according to claim 1, wherein the memory cell array comprises a boot data storage area for storing boot data, and
the recovery component performs recovery on the faulty memory cell that stores the boot data.

8. An operation method performed by a NOR flash memory, comprising:
a step of performing error checking and correcting on data read from a memory cell array through an error checking and correcting component;
a step of identifying an error pattern of a faulty memory cell for which error checking and correcting have been performed by the error checking and correcting component; and
a step of performing recovery on the faulty memory cell based on the identified error pattern to eliminate errors in the faulty memory cell.

9. The operation method according to claim 8, wherein when the error pattern indicates a decrease in a threshold of a memory cell, the recovery step comprises programming the faulty memory cell to increase the threshold.

10. The operation method according to claim 8, wherein when the error pattern indicates an increase in a threshold of a memory cell, the recovery step comprises increasing a read verification voltage of the faulty memory cell.
